(19) United States
(12) Patent Application Publication
(10) Pub. No.: US 2003/0027397 A1
(43) Pub. Date: Feb. 6, 2003

(54) Method for monitoring bipolar junction transistor emitter window etching process

(75) Inventor: Jing-Horng Gau, Hsin-Chu (TW)

Correspondence Address: LOWE HAUPTMAN GILMAN & BERNER, LLP, Suite 310, 1700 Diagonal Road, Alexandria, VA, 22314, US

(73) Assignee: United Microelectronics Corporation

(21) Appl. No.: 09/920,631

(22) Filed: Aug. 3, 2001

(51) Int. Cl. H01L 21/331

(52) U.S. Cl. 438/362

(57) ABSTRACT

A method for monitoring bipolar junction transistor emitter window etching process is disclosed. The method at least includes the following steps. First of all, a substrate is provided having a silicon oxide layer thereon and a silicon nitride layer on the silicon oxide layer. Then, a semiconductor layer is deposited on the silicon nitride layer. Next, a conductive region of a first conductivity type is formed in the semiconductor layer. Then, a dielectric layer is formed on the semiconductor layer. Then, the dielectric layer and the semiconductor layer are anisotropically etched to stop on the silicon oxide layer to define an emitter region of the bipolar junction transistor. Finally, the silicon oxide layer is isotropically etched.

### BACKGROUND OF THE INVENTION

1. Field of the Invention

The present invention generally relates to a method for forming a semiconductor device, and more particularly to a method for monitoring bipolar junction transistor emitter window etching process.

2. Description of the Prior Art

BiCMOS integrated circuits combine bipolar junction transistors and complementary MOS (CMOS) transistors on a single chip (integrated circuit), furnishing a variety of functionality and exploiting the advantages of each type of process. Thus BiCMOS integrated circuits capitalize on the relatively fast speed and better analog performance of bipolar transistors while exploiting the low power dissipation and high packing densities of CMOS transistors.

Etching rates and etch end points must be carefully monitored and controlled in order to end the etching processes at the desired time. In semiconductor processing, inadequate or an excess in etching time can result in undesirable film patterning. For instance, for semiconductor devices having film layers or features in the micron and sub-micron range, an inadequate etch or an excess etch would result in the insufficient removal or the excess removal of a desired layer. Insufficient removal of a desired layer can result in an undesired electrical open or electrical short when the desired layer to be removed is an insulator or a conductor, respectively. Additionally, if the etch is in excess, undercutting or punch through can occur resulting in poorly defined film patterning. Inadequate or excess etching time further leads to undesirable reliability problems in the subsequently fabricated semiconductor device. As a semiconductor wafer is extremely expensive due to many processing steps involved in the making thereof, the need to critically control the etching end point in an etching process is highly desirable.

An etch end point must be accurately predicted and/or detected to terminate etching abruptly. Etch rates, etch times, and etch end points are difficult to consistently predict due to lot-to-lot variations in film thickness and constitution, as well as etch bath temperature, flow, and concentration variability. That is, an etch rate is dependent upon a number of factors, which include, etchant concentration, etchant temperature, film thickness, and the film characteristics. Precise control of any of these factors can be very expensive to implement, for example, concentration control.

For the foregoing reasons, there is a necessary method for monitoring bipolar junction transistor emitter window etching process.

### SUMMARY OF THE INVENTION

In accordance with the present invention, a method is provided for monitoring bipolar junction transistor emitter window etching process that substantially can be used to easy control substrate in the present invention.

One object of the present invention is to provide a method for monitoring bipolar junction transistor emitter window etching process to obtain better quality.

Another object of the present invention is to provide a method for monitoring bipolar junction transistor emitter window etching process to easy control substrate by monitor.

In order to achieve the above object, the present invention provides a method for monitoring bipolar junction transistor emitter window etching process is disclosed. The method at least includes the following steps. First of all, a substrate is provided having a silicon oxide layer thereon and a silicon nitride layer on the silicon oxide layer. Then, a semiconductor layer is deposited on the silicon oxide layer and the silicon nitride layer. Next, a conductive region of a first conductivity type is formed in the semiconductor layer. Then, a dielectric layer is formed on the semiconductor layer. Then, the dielectric layer and the semiconductor layer are anisotropically etched to stop on the silicon oxide layer to define an emitter region of the bipolar junction transistor. Finally, the silicon oxide layer is isotropically etched.

### BRIEF DESCRIPTION OF THE DRAWINGS

The foregoing aspects and many of the attendant advantages of this invention will become more readily appreciated as the same becomes better understood by referring to the following detailed description, when taken in conjunction with the accompanying drawings, wherein:

FIG. 1A to FIG. 1F are cross-sectional views of a method for monitoring bipolar junction transistor emitter window etching process in accordance with one preferred embodiment of the present invention.

### DESCRIPTION OF THE PREFERRED EMBODIMENT

The semiconductor devices of the present invention are applicable to a broad range of semiconductor devices and can be fabricated from a variety of semiconductor materials. While the invention is described in terms of a single preferred embodiment, those skilled in the art will recognize that many steps described below can be altered without departing from the spirit and scope of the invention.

Furthermore, there is shown a representative portion of a semiconductor structure of the present invention in enlarged, cross-sections of the two dimensional views at several stages of fabrication. The drawings are not necessarily to scale, as the thickness of the various layers are shown for clarity of illustration and should not be interpreted in a limiting sense. Accordingly, these regions will have dimensions, including length, width and depth, when fabricated in an actual device.

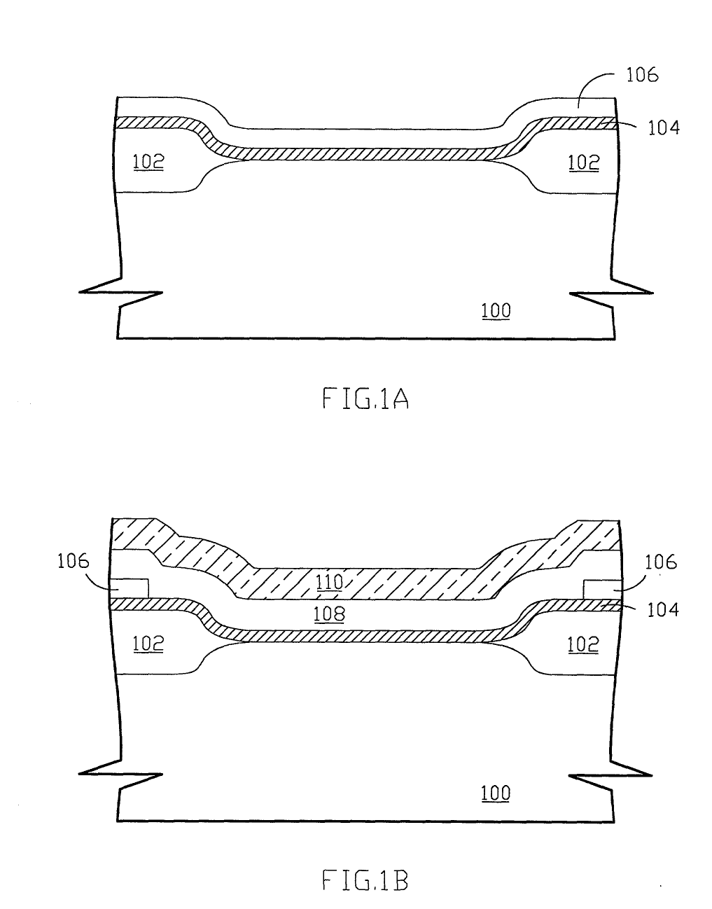

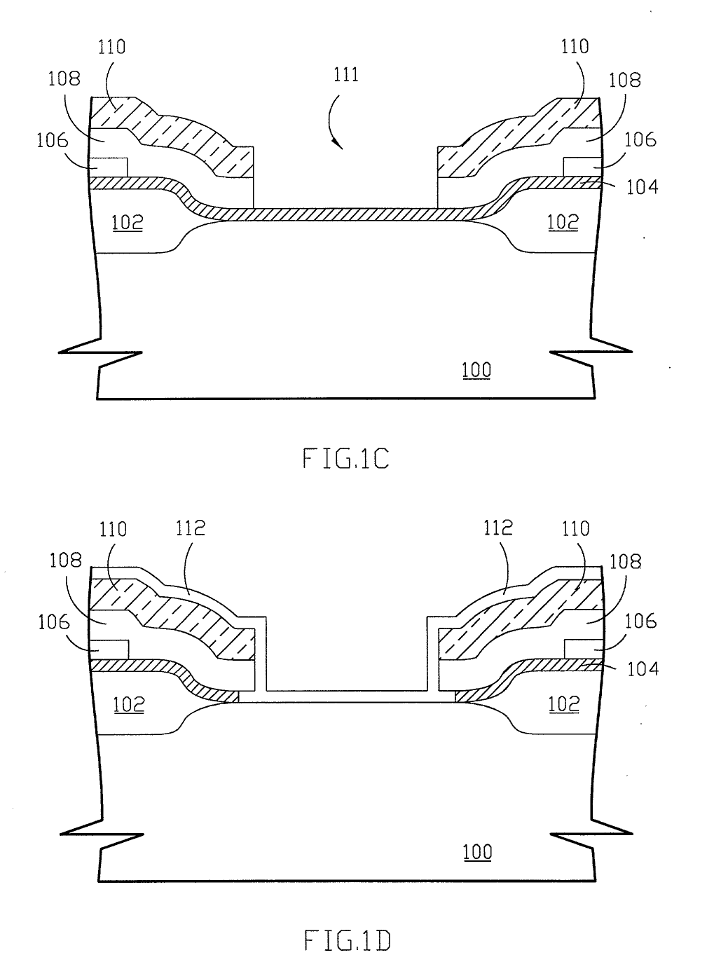

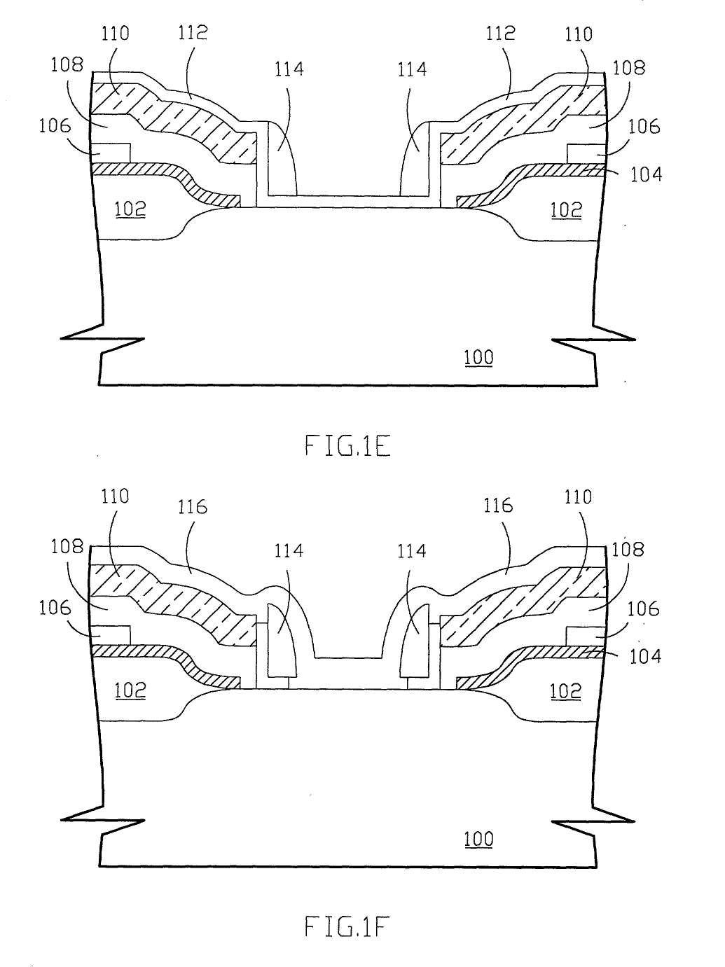

FIG. 1A to FIG. 1F are cross-sectional views of a method for monitoring bipolar junction transistor emitter window etching process in accordance with one preferred embodiment of the present invention.

Referring to FIG. 1A, depicts a process integrated circuit including a silicon wafer substrate 100 and regions of field oxide 102, which are manufactured using conventional BiCMOS methods. The field oxide (FOX) regions 102 are formed on the surface of the substrate 100 as device isolation structures. The field isolation structures surround the regions where devices are to be created and serve to define the bipolar junction transistor of the device. The FOX isolation regions 102 may be formed by the local oxidation of silicon (LOCOS) technique. Then, a silicon oxide layer 104 is formed on the substrate 100 and the field oxide regions 102. The thickness of the silicon oxide layer 104 is between about 100 and 500 angstroms. The silicon oxide layer 102 is easy to detect end-point by monitor. Because the etch selectivity of the silicon oxide layer 102 is different from the substrate 100. Next, a first dielectric layer 106 is formed on the silicon oxide layer 104. The first dielectric layer 106 comprises silicon nitride. The thickness of the first dielectric layer 106 is between about 300 and 500 angstroms. The first dielectric layer 106 is formed by using low pressure chemical vapor deposition (LPCVD).

For example, an n-type silicon wafer substrate 100 may be processed to form various passive devices and active devices, including p-channel CMOS transistors and bipolar transistors. In this exemplary BiCMOS process, n+ antimony implant layers may be buried into a p-type substrate wherever a NPN bipolar transistor or PMOS device is to be formed. Similarly, p-type boron impurities may be implanted to form a p+ well wherever a NMOS device is to be formed.

Masking to define regions for thick oxide growth forms Field oxide regions 102. A layer of silicon nitride is deposited and patterned with a mask, leaving silicon nitride only in regions where active devices are to be placed. These regions are then etched down into the epitaxial layer. Field oxide growth is performed by local oxidation to isolate active devices from one another.

Referring to FIG. 1B, a first photoresist layer (not show in FIG) is deposited on the first dielectric layer 106. The first photoresist layer has an opening by using conventional lithographic technology. Then, the first dielectric layer 106 is etched by using the first photoresist layer as a mask. Next, a portion of the first dielectric layer 106 is removed to expose the silicon oxide layer 104 to define a region for a bipolar junction transistor. Then, a first semiconductor layer 108 is deposited on the silicon oxide layer 104. The first semiconductor layer 108 compresses amorphous silicon or polysilicon. The thickness of the first semiconductor layer 108 is between about 500 and 3000 angstroms. Simultaneously, numerous ions are p-type implanted in the first semiconductor layer 108, whereby, available varieties of ions at least include B⁺³. Then, a second dielectric layer 110 is deposited on the first semiconductor layer 108. The second dielectric layer 110 comprises silicon nitride. The thickness of the second dielectric layer 110 is between about 1000 and 5000 angstroms. The second dielectric layer 110 is formed by using low pressure chemical vapor deposition (LPCVD), plasma enhanced chemical vapor deposition (PECVD) or atmospheric chemical vapor deposition (APCVD).

Referring to FIG. 1C, a second photoresist layer (not show in FIG) is deposited on the second dielectric layer 110. The second photoresist layer has an opening by using conventional lithographic technology. Then, the second dielectric layer 110 and the first semiconductor layer 108 are etch to stop on the silicon oxide layer 102 to define an emitter region 111 of the bipolar junction transistor by using the second photoresist layer as a mask. The emitter region 112 is formed by anisotropically etching.

Referring to FIG. 1D, the silicon oxide layer 104 is etched under the first semiconductor layer 108. An etching method is isotropically etching. The isotropically etching caused under-cut under the first semiconductor layer 108. Then, a second conformal semiconductor layer 112 is deposited on the substrate 100, sidewall of the emitter region 111, and the second dielectric layer 110. The second conformal semiconductor layer 112 comprises amorphous silicon or polysilicon. The thickness of the second conformal semiconductor layer 112 is between about 100 and 200 angstroms. In the embodiment, thickness of this layer is preferable 120 angstroms. The first semiconductor layer 108, emitter region 111 and the under-cut filled the second conformal semiconductor layer 112.

Referring to FIG. 1E, the second conformal semiconductor layer 112 is oxidized to form an oxide layer 112a. Simultaneously, numerous ions are implanted drive in the substrate 100, whereby, available varieties of ions at least include B⁺³. Then, a third dielectric layer (not show in FIG) is deposited on the oxide layer 112a and emitter region 111. The third dielectric layer comprises silicon nitride. Then, etch back the third dielectric layer to form the silicon nitride spacer 114 on sidewall of the emitter region 111.

Referring to FIG. 1F, the oxide layer 112a is etched by isotropically etching method. Then, the third conformal semiconductor layer 116 is deposited on the substrate 100, the second dielectric layer 110, and the spacer 118a surface. Finally, n-type numerous ions are implanted in the third conformal semiconductor layer 116, whereby, available varieties of ions at least include arsenic.

The method for monitoring bipolar junction transistor emitter window etching process using the above explained method, has the following advantages:

1. The present invention is to provide a method for monitoring bipolar junction transistor emitter window etching process that means substrate will not receive dry etch damage which can obtain better quality.

2. The present invention is to provide a method for monitoring bipolar junction transistor emitter window etching process that means the oxide layer is stop layer can easy control etch that no etch problem of substrate.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for performing bipolar junction transistor emitter window etching process, said method comprising the steps of:
providing a substrate having a silicon oxide layer thereon, a silicon nitride layer on said silicon oxide layer, a semiconductor layer on said silicon nitride layer, a conductive region of a first conductivity type in said semiconductor layer, and a dielectric layer on said semiconductor layer;
etching said dielectric layer and said semiconductor layer anisotropically to stop on said silicon oxide layer to define an emitter region of said bipolar junction transistor; and
etching said silicon oxide layer isotropically.

2. The method according to claim 1, wherein said substrate comprises silicon.

3. The method according to claim 1, wherein thickness of said silicon oxide layer is between about 200 and 300 angstroms.

4. The method according to claim 1, wherein said dielectric layer comprises silicon nitride.

5. The method according to claim 1, wherein said semiconductor layer is selected from the group consisting of amorphous silicon and polysilicon.

6. A method for forming a bipolar junction transistor on a substrate having a metal-oxide-semiconductor transistor formed therein and thereon, said method comprising the steps of:
forming a silicon oxide layer on said substrate;
passivating said metal-oxide-semiconductor transistor by using a first dielectric layer;
depositing a first semiconductor layer on said first dielectric layer;
forming a first conductive region of a first conductivity type in said semiconductor layer;
forming a second dielectric layer on said first semiconductor layer;
etching said second dielectric layer and said first semiconductor layer anisotropically to stop on said silicon oxide layer to define an emitter region of said bipolar junction transistor;
etching said silicon oxide layer isotropically;
depositing a conformal second semiconductor layer on said substrate, sidewall of said emitter region and said second dielectric layer;
oxidizing said second semiconductor layer to form an oxide layer;
forming silicon nitride spacer on sidewall of said emitter region;
etching said oxide layer isotropically;
depositing a third semiconductor on said substrate; and
forming a second conductive region of a second conductivity type opposite to said first conductivity type in said third semiconductor layer.

7. The method according to claim 6, wherein said substrate comprises silicon.

8. The method according to claim 6, wherein thickness of said silicon oxide layer is between about 200 and 300 angstroms.

9. The method according to claim 6, wherein said first dielectric layer comprises silicon nitride.

10. The method according to claim 6, wherein said second dielectric layer comprises silicon nitride.

11. The method according to claim 6, wherein said first semiconductor layer is selected from the group consisting of amorphous silicon and polysilicon.

12. The method according to claim 6, wherein said second semiconductor layer is selected from the group consisting of amorphous silicon and polysilicon.

13. The method according to claim 6, wherein said third semiconductor layer is selected from the group consisting of amorphous silicon and polysilicon.

14. A method for forming semiconductor, said method comprising;
providing a substrate;
depositing a silicon oxide layer on said substrate and a first silicon nitride layer on said silicon oxide layer;
removing a portion of said first silicon nitride layer to expose said silicon oxide layer to define a region for a bipolar junction transistor;
depositing a first semiconductor layer on said silicon nitride layer;
forming a first conductive region of a first conductivity type in said first semiconductor layer;
depositing a second silicon nitride layer on said first semiconductor layer;
etching said second silicon nitride layer and said first semiconductor layer to stop on said silicon oxide layer to define an emitter region of said bipolar junction transistor;
etching said silicon oxide layer isotropically;
depositing a conformal second semiconductor layer on said substrate, sidewall of said emitter region and said silicon nitride layer;
oxidizing said second semiconductor layer to form an oxide layer;
forming a silicon nitride spacer on sidewall of said emitter region;
etching said oxide layer isotropically;
depositing a third semiconductor layer on said substrate; and
forming a second conductive region of a second conductivity type opposite to said first conductivity type in said third semiconductor layer.

15. The method according to claim 14, wherein said substrate comprises silicon.

16. The method according to claim 14, wherein thickness of said silicon oxide layer is between about 200 and 300 angstroms.

17. The method according to claim 14, wherein said first semiconductor layer is selected from the group consisting of amorphous silicon and polysilicon.

18. The method according to claim 14, wherein said second semiconductor layer is selected from the group consisting of amorphous silicon and polysilicon.

19. The method according to claim 14, wherein said third semiconductor layer is selected from the group consisting of amorphous silicon and polysilicon.
